(19) United States
(12) Patent Application Publication
(10) Pub. No.: US 2024/0186459 A1
(43) Pub. Date: Jun. 6, 2024

(54) LIGHT EMITTING STRUCTURE

(71) Applicant: PROLIGHT OPTO TECHNOLOGY CORPORATION, Taoyuan City (TW)

(72) Inventors: Chen-Lun HSING CHEN, Taoyuan City (TW); Jung-Hao HUNG, Taoyuan City (TW); Yung-Chun YANG, Taoyuan City (TW)

(21) Appl. No.: 18/528,489

(22) Filed: Dec. 4, 2023

(30) Foreign Application Priority Data
Dec. 6, 2022 (TW) 111146695

(51) Int. Cl. H01L 33/48; H01L 33/60; H01L 33/62; H01L 33/64

(52) U.S. Cl. CPC H01L 33/483; H01L 33/60; H01L 33/62; H01L 33/648

(57) ABSTRACT

A light emitting structure includes a carrying unit, a light emitting unit and a light transmitting unit. The light emitting unit is arranged on the carrying unit, and includes a light emitting surface. The light transmitting unit directly contacts the light emitting unit, and includes a first surface and a second surface opposite to each other. The first surface covers at least part of the light emitting surface, and the second surface directly contacts a gas.

### BACKGROUND OF THE DISCLOSURE

### Technical Field

The present disclosure relates to a light emitting structure, particularly relates to a light emitting structure which may enhance the output intensity of red light.

### Description of Related Art

Light emitting diode (LED) is one kind of semiconductor element, which is mainly transforming the electrical energy to the light energy through semiconductor compound to achieve the light effect. LED has the advantages of long service life, high stability, and low power consumption, thereby being widely applied in the lighting nowadays. Following the relatively mature development of blue and green light chip technology, in order to match the application field of professional lighting (for example, theater stage, artistic exhibition, or medical equipment application, etc.), the output intensity of the red light is relatively important, when considering the need of RGB mixing application and color rendering index (CRI).

In the related art, the package is mostly covered by the colloid material for protecting the chip, preventing the gold wire from being damaged and failed, and further changing light emitting angle and increasing brightness of the chip.

Following the application, such as the development of package technology, increasing of power requirement, decreasing of package volume, and multi-chip-multi-color, etc., new package style is developed. In the related-art LED package style, such as lamp type, plastic leaded chip carrier (PLCC) type, surface mount device (SMD) type, etc., the colloid material is used to cover the chip. The reason is 1) protecting the chip and gold wire from being damaged by external force and being failed, 2) increasing chip brightness, and 3) changing light emitting angle. However, regardless of which kind of package in the related art, no process is used for single color light chip except for the blue light chip with phosphor powder as being transformed into the white light LED. At the same time, the package brightness (lm or mW) of LED is related to the brightness of the die. As a result, the brightness may have 20%-30% loss according to different wavelength.

In view of this, the inventors have devoted themselves to the aforementioned related art, researched intensively try to provide a light emitting structure for increasing the brightness to solve the problem in the related art.

### SUMMARY OF THE DISCLOSURE

One purpose of the disclosure is to provide a light emitting structure, which may increase the red light brightness of new package style to achieve the purpose of simple structure, easy manufacturing, and low manufacturing cost.

In order to achieve the purpose, the disclosure provides a light emitting structure includes a carrying unit, a light emitting unit, and a light transmitting unit. The light emitting unit is disposed on the carrying unit, and has a light emitting surface. The light transmitting unit directly contacts the light emitting unit, and has a first surface and a second surface opposite to each other. The first surface covers at least a part of the light emitting surface, and the second surface directly contacts a gas.

In some embodiments, an area of the light transmitting unit covering the light emitting unit is greater than or equal to 0.8 times and less than or equal to 1.2 times an area of the light emitting surface.

In some embodiments, the light emitting structure further includes a reflection unit. The reflection unit is disposed on the carrying unit, and surrounds a periphery of the light emitting unit.

In some embodiments, the reflection unit includes a white colloid surrounding the periphery of the light transmitting unit.

In some embodiments, the second surface of the light transmitting unit is a plane or a curved surface defined by a surface tension.

In some embodiments, the light emitting structure further includes a light transmitting cover. The light transmitting cover is disposed on the carrying unit, and covers the light emitting unit and the light transmitting unit.

In some embodiments, the light transmitting cover includes a ventilating hole defined adjacent to a periphery of the carrying unit.

In some embodiments, the gas includes an inert gas and an atmosphere.

In some embodiments, the carrying unit includes a substrate and a lead frame.

In some embodiments, a peak emission wavelength of the light emitting unit is greater than or equal to 600 nm, and a refractive index of the light transmitting unit is greater than or equal to 1.3.

In summary, the light emitting structure of the disclosure uses the structure of the light emitting unit directly contacting the light transmitting unit to make the red light wavelength with lower energy be captured and accumulated, and make the red light outputted from the light transmitting unit have certain level of light intensity. Further, regarding the red light wavelength with lower energy, comparing to the related-art of directly emitting to the atmosphere, the light transmitting unit provides an optical chamber having lower refractive index variation to avoid outputted energy loss of the red light. Further, the phosphor powder or phosphor layer may not need to be arranged to decrease the manufacturing difficulty and cost.

Further, the light emitting structure of the disclosure may increase the output intensity of the red light in the new package style to achieve the purpose of simple structure, easy manufacturing, and low manufacturing cost.

It is worth mentioning that the style of LED contacting gas instead of packaging colloid along the light emitting direction may be called “air-type” architecture. The disclosure is mainly about the packaging technology for “air-type” architecture to increase lighting effect (for example, increasing brightness of red light).

### BRIEF DESCRIPTION OF THE DRAWINGS

FIG. 1A and FIG. 1B are the cross-sectional diagrams of the light emitting structure in the first embodiment of the disclosure.

FIG. 2 is the cross-sectional diagram of the light emitting structure in the second embodiment of the disclosure.

FIG. 3 is the cross-sectional diagram of the light emitting structure in the third embodiment of the disclosure.

FIG. 4 is the top view of the light emitting structure in the third embodiment of the disclosure.

FIG. 5 is the cross-sectional diagram of the light emitting structure in the fourth embodiment of the disclosure.

FIG. 6 is the cross-sectional diagram of the light emitting structure in the fifth embodiment of the disclosure.

FIG. 7 is the relation diagram of the brightness proportion and the thickness of the light transmitting unit of the disclosure.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

A detailed description and technical content of the present disclosure are described as follows with the accompanying drawings.

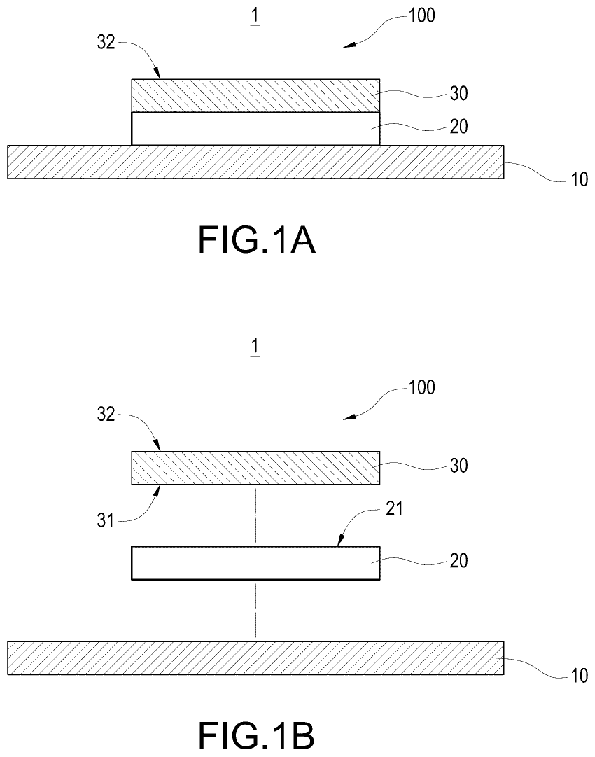

FIG. 1A and FIG. 1B are the cross-sectional diagrams of the light emitting structure 1 in the first embodiment of the disclosure.

As shown in FIG. 1A and FIG. 1B, the light emitting structure 1 in the first embodiment of the disclosure includes a carrying unit 10, a light emitting unit 20, and a light transmitting unit 30.

The carrying unit 10 is used to carry the light emitting unit 20 and the light transmitting unit 30.

In some embodiments, the carrying unit 10 may be made of the materials, such as aluminum nitride, aluminum oxide, positron emission tomography (PET), bismaleimide triazine (or BT resin), or ceramics, etc., here is not intended to be limiting.

In some embodiments, the carrying unit 10 may be a printed circuit board (PCB), a ceramics substrate with circuit pattern, or a lead frame, etc. Further, as the first embodiment in the FIG. TA, the carrying unit 10 is a substrate in a planar plate shape, here is not intended to be limiting, the carrying unit 10 may also be a lead frame in a cup shape.

The light emitting unit 20 is disposed on the carrying unit 10, and has a light emitting surface 21.

In some embodiments, the light emitting unit 20 receives the power from the carrying unit 10 to emit the light. For example, the power is received through the conductive line made by the materials, such as Al, Ag, Cu, Ni, Pd, Au, etc. In some other embodiments, the power may be received through the transparent conductive material (for example, indium tin oxide (ITO), etc.), here is not intended to be limiting.

In some embodiments, a peak emission wavelength (WLP) of the light emitting unit 20 is greater than or equal to 600 nm, particularly greater than or equal to 600 nm and less than or equal to 680 nm. In other words, or greater than or equal to 570 nm and less than or equal to 750 nm, visual color of the light outputted from the light emitting unit 20 is red light corresponding to the visible light range, here is not intended to be limiting.

In some embodiments, the light emitting unit 20 may further include the red light LED (for example, the materials of AlGaAs, GaAsP, AlGaInP, or GaP:ZnO, etc.), orange light LED (for example, the materials of GaAsP, AlGaIn, AlGaInP, or GaP:N, etc.), green light LED (for example, the materials of InGaN, GaN, GaP, AlGaInP, or AlGaP, etc.), blue light LED (for example, the materials of ZnSe, InGaN, or SiC, etc.), and/or purple light LED (for example, the materials of InGaN, etc.) in the visible light range, and/or the infrared LED (for example, the materials of GaAs, or AlGaAs, etc.), or ultraviolet LED (for example, the materials of diamond, AlN, AlGaN, or AlGaInN, etc.). Moreover, the type of LED may also include organic light-emitting diode (OLED), here is not intended to be limiting.

The light transmitting unit 30 directly contacts the light emitting unit 20, and has a first surface 31 and a second surface 32 opposite to each other. Further, the first surface 31 covers at least a part of the light emitting surface 21, and the second surface 32 directly contacts a gas 100. The style of LED contacting gas 100 instead of packaging colloid along the light emitting direction may be called “air-type” architecture. Further, the gas 100 may include an inert gas and an atmosphere, here is not intended to be limiting.

In some embodiments, an area of the light transmitting unit 30 covering the light emitting unit 20 is greater than or equal to 0.8 times and less than or equal to 1.2 times an area of the light emitting surface 21.

In some embodiments, the second surface 32 of the light transmitting unit 30 is a plane or a curved surface defined by a surface tension. Further, as the first embodiment in FIG. 1B, the second surface 32 of the light transmitting unit 30 is a plane parallel to the light emitting unit 20, here is not intended to be limiting.

In some embodiments, the refractive index of the light transmitting unit 30 is greater than or less than 1.3. The light transmitting unit 30 may include the material of quartz, glass, ceramics, silicone, epoxy, or silicone-epoxy compound made by aforementioned materials, here is not intended to be limiting.

It is worth mentioning that the light transmitting unit 30 in the disclosure directly contacts the light emitting unit 20 and the gas 100. Regarding the refractive index, the refractive indexes of atmosphere to the light with all kinds of frequency are close to 1. For example, in an environment of 20° C. and atmospheric pressure under 760 mmHg, the refractive index is 1.00027, and the refractive index related to the substrate, such as the material of quartz, acrylic, or flint glass, is between 1.45 to 1.9. Regarding the light transmission, when the transmission is under the state of greater refractive index difference, the energy loss of the light may be higher dependently. Therefore, the disclosure uses the structure of directly covering the light emitting unit 20 with the light transmitting unit 30, and the refractive index of the light transmitting unit 30 is between that of the light emitting unit 20 and that of the gas 100 (for example, atmosphere or inert gas) to make the light emitting surface 21 of the light emitting unit 20 free from directly contacting the gas 100. As a result, when the light is transmitted from the light emitting unit 20 to the light transmitting unit 30 and transmitted from the light transmitting unit 30 to the gas 100, the refractive index difference and the energy loss may be minimal. Particularly, WLP outputted by the light emitting unit 20 is greater than or equal to 600 nm, comparing to the related art of no light transmitting unit 30, the disclosure may enhance the light intensity by 10% to 20%, for example, 117% to the related art, here is not intended to be limiting.

In summary, the light emitting structure 1 of the disclosure uses the structure of the light emitting unit 20 directly contacting the light transmitting unit 30 to make the red light wavelength with lower energy (for example, greater than or equal to 600 nm) be captured and accumulated (that is, between the first surface 31 and the second surface 32 of the light transmitting unit 30), and make the red light outputted from the light transmitting unit 30 have certain level of light intensity. Further, regarding the red light wavelength with lower energy, comparing to the related-art of directly emitting to the atmosphere, the light transmitting unit 30 provides an optical chamber having lower refractive index variation to avoid outputted energy loss of the red light. Further, the light emitting structure of the disclosure may increase the output intensity of the red light in the new package style to achieve the purpose of simple structure, easy manufacturing, and low manufacturing cost.

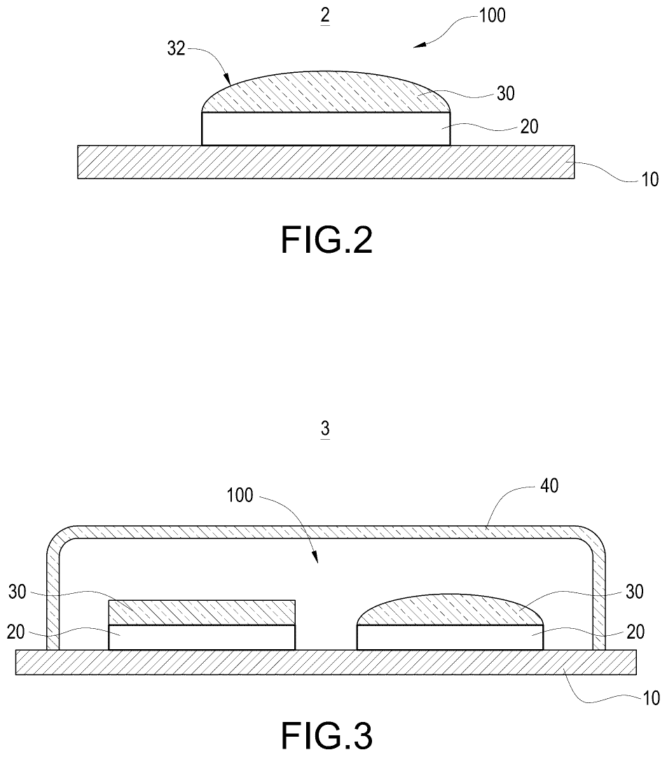

FIG. 2 is the cross-sectional diagram of the light emitting structure 2 in the second embodiment of the disclosure.

Referring to FIG. TA to FIG. 2, the light emitting structure 2 in the second embodiment is similar to the light emitting structure 1 in the first embodiment, the difference therebetween is that the second surface 32 of the light transmitting unit 30 in the light emitting structure 2 is a curved surface formed by a surface tension, here is not intended to be limiting.

In summary, the light emitting structure 2 of the disclosure uses the structure of the light emitting unit 20 directly contacting the light transmitting unit 30 to make the red light wavelength with lower energy (for example, greater than or equal to 600 nm) be captured and accumulated (that is, between the first surface 31 and the second surface 32 of the light transmitting unit 30), and make the red light outputted from the light transmitting unit 30 have certain level of light intensity. Further, regarding the red light wavelength with lower energy, comparing to the related-art of directly emitting to the atmosphere, the light transmitting unit 30 provides an optical chamber having lower refractive index variation to avoid outputted energy loss of the red light. Further, the light emitting structure of the disclosure may increase the output intensity of the red light in the new package style to achieve the purpose of simple structure, easy manufacturing, and low manufacturing cost.

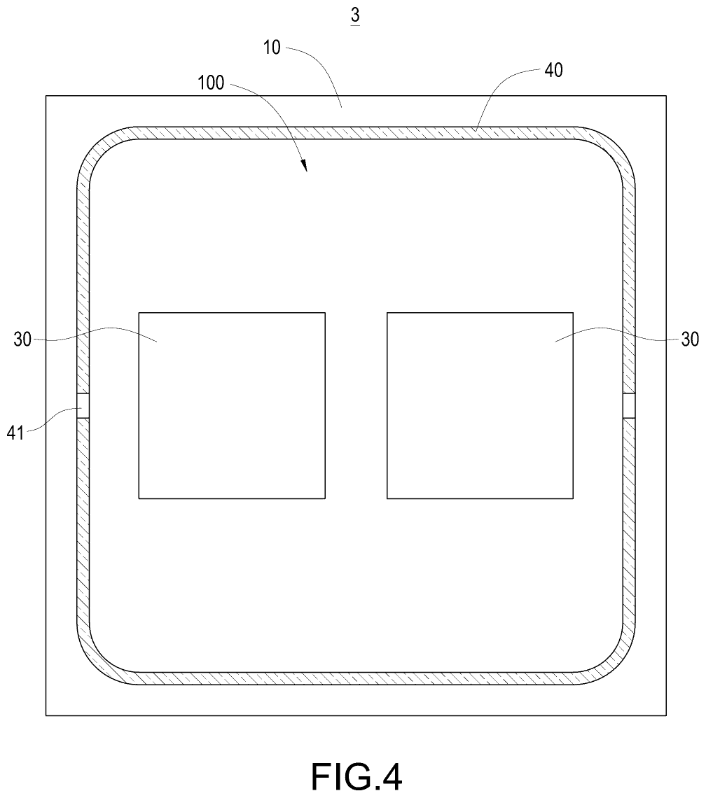

FIG. 3 is the cross-sectional diagram of the light emitting structure 3 in the third embodiment of the disclosure. FIG. 4 is the top view of the light emitting structure 3 in the third embodiment of the disclosure.

Referring to FIG. 3 and FIG. 4, the light emitting structure 3 in the third embodiment is similar to the light emitting structure 1 in the first embodiment and the light emitting structure 2 in the second embodiment, the difference therebetween is that the light emitting structure 3 may further include a light transmitting cover 40 (or transparent cover).

In some embodiments, the light transmitting cover 40 is disposed on the carrying unit 10, and covers the light emitting unit 20 and the light transmitting unit 30 to protect the light emitting unit 20 and the light transmitting unit 30, here is not intended to be limiting.

In some embodiments, the light transmitting cover 40 may include glass, quartz, sapphire, etc., here is not intended to be limiting.

In some embodiments, the light transmitting cover 40 may include at least one ventilating hole 41 defined adjacent to a periphery of the carrying unit 10 for communicating the gas 100 (for example, atmosphere or inert gas) inside and outside the light transmitting cover 40 to cool down the light emitting unit 20 and increase the service life and reliability of the light emitting unit 20, here is not intended to be limiting.

In summary, the light emitting structure 3 of the disclosure uses the structure of the light emitting unit 20 directly contacting the light transmitting unit 30 to make the red light wavelength with lower energy (for example, greater than or equal to 600 nm) be captured and accumulated (that is, between the first surface 31 and the second surface 32 of the light transmitting unit 30), and make the red light outputted from the light transmitting unit 30 have certain level of light intensity. Further, regarding the red light wavelength with lower energy, comparing to the related-art of directly emitting to the atmosphere, the light transmitting unit 30 provides an optical chamber having lower refractive index variation to avoid outputted energy loss of the red light. Further, the light emitting structure of the disclosure may increase the output intensity of the red light in the new package style to achieve the purpose of simple structure, easy manufacturing, and low manufacturing cost.

Further, in some embodiments, the light transmitting cover 40 may cover the light emitting unit 20 and the light transmitting unit 30 to protect the light emitting unit 20 and the light transmitting unit 30.

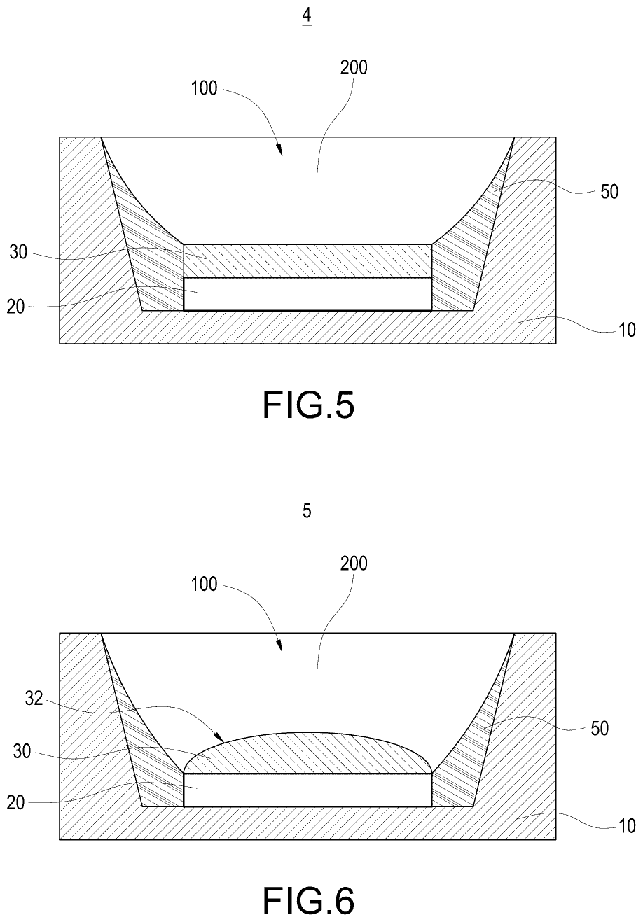

FIG. 5 is the cross-sectional diagram of the light emitting structure 4 in the fourth embodiment of the disclosure.

Referring to FIG. 5, the light emitting structure 4 in the fourth embodiment is similar to the light emitting structure 1 in the first embodiment, the difference therebetween is that the light emitting structure 4 further includes a reflection unit 50, and the carrying unit 10 is a lead frame. The lead frame may have a cup structure, and the light emitting unit 20 and the light transmitting unit 30 are disposed on a center position of the carrying unit 10.

In some embodiments, the reflection unit 50 may include a polymer material with high reflectivity in white color or a white colloid made of metal oxide (for example, TiO₂, etc.). The reflection unit 50 surrounds peripheries of the light emitting unit 20 and the light transmitting unit 30 to enhance the reflectivity around the periphery of the light emitting unit 20 and avoid part of the light energy being lost from the periphery of the light emitting unit 20. Therefore, the energy loss of the light intensity may be decreased.

In some embodiments, when the lead frame is in the cup structure, the cover structure may be omitted to reduce light loss. In some other embodiments, a cover may be used to cover the carrying unit 10 for protecting the light emitting unit 20, the light transmitting unit 30, and the reflection unit 50. A space 200 is defined between the cover, the carrying unit 10, the light transmitting unit 30, and the reflection unit 50 for accommodating the gas 100, here is not intended to be limiting.

In summary, the light emitting structure 4 of the disclosure uses the structure of the light emitting unit 20 directly contacting the light transmitting unit 30 to make the red light wavelength with lower energy (for example, greater than or equal to 600 nm) be captured and accumulated (that is, between the first surface 31 and the second surface 32 of the light transmitting unit 30), and make the red light outputted from the light transmitting unit 30 have certain level of light intensity. Further, regarding the red light wavelength with lower energy, comparing to the related-art of directly emitting to the atmosphere, the light transmitting unit 30 provides an optical chamber having lower refractive index variation to avoid outputted energy loss of the red light. Further, the light emitting structure of the disclosure may increase the output intensity of the red light in the new package style to achieve the purpose of simple structure, easy manufacturing, and low manufacturing cost.

It is worth mentioning that the light emitting structure 4 of the disclosure includes the reflection unit 50 surrounding the periphery of the light emitting unit 20. The reflection unit 50 may prevent the light outputted from the light emitting unit 20 escaping from the sidewall of the light emitting unit 20 and avoid energy loss. Further, the reflection unit 50 restricts the lighting angle of the light emitting unit 20, and may let more light enter the light transmitting unit 30 to enhance the illumination of the light emitting structure 4 of the disclosure comparing to the lighting product in the related art.

In some embodiments, the light emitting structure 4 of the disclosure may increase the illumination by 10% with the reflection unit 50 comparing to the related art.

FIG. 6 is the cross-sectional diagram of the light emitting structure 5 in the fifth embodiment of the disclosure.

Referring to FIG. 6, the light emitting structure 5 in the fifth embodiment is similar to the light emitting structure 4 in the fourth embodiment, the difference therebetween is that the second surface 32 of the light emitting unit 30 is a curved surface formed by the surface tension.

The reflection unit 50 only surrounds the periphery of the light emitting unit 20 without contacting the light transmitting unit 30. The other curved surface of the reflection unit 50 may be formed by the surface tension between the light emitting unit 20 and the carrying unit 10, here is not intended to be limiting.

In summary, the light emitting structure 5 of the disclosure uses the structure of the light emitting unit 20 directly contacting the light transmitting unit 30 to make the red light wavelength with lower energy (for example, greater than or equal to 600 nm) be captured and accumulated (that is, between the first surface 31 and the second surface 32 of the light transmitting unit 30), and make the red light outputted from the light transmitting unit 30 have certain level of light intensity. Further, regarding the red light wavelength with lower energy, comparing to the related-art of directly emitting to the atmosphere, the light transmitting unit 30 provides an optical chamber having lower refractive index variation to avoid outputted energy loss of the red light. Further, the light emitting structure of the disclosure may increase the output intensity of the red light in the new package style to achieve the purpose of simple structure, easy manufacturing, and low manufacturing cost.

It is worth mentioning that the light emitting structure 5 of the disclosure includes the reflection unit 50 surrounding the periphery of the light emitting unit 20. The reflection unit 50 may prevent the light outputted from the light emitting unit 20 escaping from the sidewall of the light emitting unit 20 and avoid energy loss. Further, the reflection unit 50 restricts the lighting angle of the light emitting unit 20, and may let more light enter the light transmitting unit 30 to enhance the brightness of the light emitting structure 4 of the disclosure comparing to the lighting product in the related art.

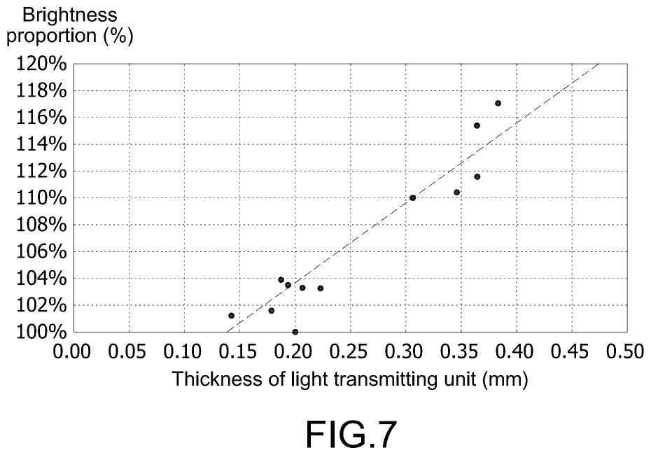

FIG. 7 is the relation diagram of the brightness proportion and the thickness of the light transmitting unit 30 of the light emitting structures 1-5 in the disclosure.

Referring to FIG. TA to FIG. 7, the light transmitting unit 30 is used to accumulate the light outputted from the light emitting unit 20, and make the light outputted from the light transmitting unit 30 have certain level of light intensity, as the experimental value and trending line in the FIG. 7. Further, the light transmitting unit 30 may be considered as an optical resonator. When the chamber volume of the optical resonator is properly increased, more light energy may be accumulated. Therefore, when the thickness of the light transmitting unit 30 is properly increased, more light energy may be accumulated to increase the light intensity outputted from the light transmitting unit 30. Particularly, regarding the red light (for example, the wavelength between 600 nm to 680 nm, or between 570 nm to 750 nm) with lower energy, when the thickness (for example, the thickness between 0.05 mm and 1.0 mm) of the light transmitting unit 30 is properly increased, the light intensity is desirably increased. For example, the brightness may be increased to between 101% to 120%, here is not intended to be limiting.

In summary, the light emitting structure of the disclosure uses the structure of the light emitting unit directly contacting the light transmitting unit to make the red light wavelength with lower energy be captured and accumulated, and make the red light outputted from the light transmitting unit have certain level of light intensity. Further, regarding the red light wavelength with lower energy, comparing to the related-art of directly emitting to the atmosphere, the light transmitting unit provides an optical chamber having lower refractive index variation to avoid outputted energy loss of the red light. Further, the phosphor powder or phosphor layer may not need to be arranged to decrease the manufacturing difficulty and cost.

In some embodiments, the light transmitting cover may include at least one ventilating hole defined adjacent to a periphery of the carrying unit for communicating the gas (for example, atmosphere or inert gas) inside and outside the light transmitting cover to cool down the light emitting unit and increase the service life and reliability of the light emitting unit.

In some embodiments, the light emitting structure of the disclosure includes the reflection unit surrounding the periphery of the light emitting unit. The reflection unit may prevent the light outputted from the light emitting unit escaping from the sidewall of the light emitting unit and avoid energy loss. Further, the reflection unit restricts the lighting angle of the light emitting unit, and may let more light enter the light transmitting unit to enhance the illumination of the light emitting structure of the disclosure comparing to the lighting product in the related art.

It is worth mentioning that, when the thickness of the light transmitting unit is properly increased, more light energy may be accumulated to increase the light intensity outputted from the light transmitting unit. Particularly, regarding the red light (for example, the wavelength between 600 nm to 680 nm, or between 570 nm to 750 nm) with lower energy, when the thickness of the light transmitting unit is properly increased, the light intensity is desirably increased.

Therefore, the disclosure is to provide a light emitting structure, which may increase the red light brightness of new package style without packaging colloid material to increase the output intensity, and achieve the purpose of simple structure, easy manufacturing, and low manufacturing cost.

While this disclosure has been described by means of specific embodiments, numerous modifications and variations may be made thereto by those skilled in the art without departing from the scope and spirit of this disclosure set forth in the claims.

What is claimed is:

1. A light emitting structure, comprising:
a carrying unit;
a light emitting diode, disposed on the carrying unit, and comprising a light emitting surface, wherein a peak emission wavelength of the light emitting diode is greater than or equal to 570 nm and less than or equal to 750 nm;
a light transmitting unit, directly contacting the light emitting diode, and comprising a first surface and a second surface opposite to each other, wherein a refractive index of the light transmitting unit is greater than or equal to 1.3, a thickness of the light transmitting unit is between 0.05 mm and 1.0 mm, an area of the light transmitting unit covering the light emitting diode is greater than or equal to 0.8 times and less than or equal to 1.2 times an area of the light emitting surface,
wherein the first surface covers at least a part of the light emitting surface, and the second surface directly contacts a gas.

2. The light emitting structure according to claim 1, further comprising:
a reflection unit, disposed on the carrying unit, and surrounding a periphery of the light emitting diode.

3. The light emitting structure according to claim 2, wherein the reflection unit comprises a white colloid surrounding the periphery of the light transmitting unit.

4. The light emitting structure according to claim 1, wherein the second surface of the light transmitting unit is a plane or a curved surface defined by a surface tension.

5. The light emitting structure according to claim 1, further comprising:
a light transmitting cover, disposed on the carrying unit, and covering the light emitting unit and the light transmitting unit.

6. The light emitting structure according to claim 5, wherein the light transmitting cover comprises a ventilating hole defined adjacent to a periphery of the carrying unit.

7. The light emitting structure according to claim 1, wherein the gas comprises an inert gas and an atmosphere.

8. The light emitting structure according to claim 1, wherein the carrying unit comprises a substrate and a lead frame.
